(19) United States
(12) Patent Application Publication
(10) Pub. No.: US 2009/0114937 A1
(43) Pub. Date: May 7, 2009

(54) RESIN-SEALED LIGHT EMITTING DEVICE AND ITS MANUFACTURING METHOD

(76) Inventor: Kazuki KAWAKUBO, Kyoto-shi (JP)

Correspondence Address: BIRCH STEWART KOLASCH & BIRCH, PO BOX 747, FALLS CHURCH, VA, 22040-0747, US

(21) Appl. No.: 12/262,557

(22) Filed: Oct. 31, 2008

(30) Foreign Application Priority Data
Nov. 5, 2007 (JP) 2007-287546(P)

(51) Int. Cl. H01L 33/00; H01L 21/00

(52) U.S. Cl. 257/98; 438/29; 257/E33.001; 257/E21.001

(57) ABSTRACT

An LED package is formed by separating a sealed body containing a substrate having a plurality of regions into individual bodies. The LED package includes an LED chip mounted on a recessed part in an upper surface of a substrate, a sealing resin to cover an entire surface of the region, a setting pattern provided on a bottom surface of the recessed part to set the LED chip, a wiring pad provided on the bottom surface of the recessed part, a wiring pattern provided on a slanted surface of the recessed part and serving as a light reflection part also, a wire to connect an electrode of the LED chip to the wiring pad, an external terminal provided on a lower surface of the substrate, a connection part to connect the wiring pattern connected to the wiring pad to the external terminal, and a heat radiating pattern provided on a lower surface to radiate a heat generated in the LED chip outside the LED package. The setting pattern is connected to the heat radiating pattern through the connection part.

This nonprovisional application is based on Japanese Patent Application No. 2007-287546 filed on Nov. 5, 2007 with the Japan Patent Office, the entire contents of which are hereby incorporated by reference.

### BACKGROUND OF THE INVENTION

1. Field of the Invention

The present invention relates to a resin-sealed light emitting device having excellent heat radiation characteristics and luminance efficiency, and its manufacturing method.

2. Description of the Background Art

A conventional method for producing a resin-sealed light emitting device (referred to as the “LED package” occasionally hereinafter) by sealing an LED chip with a translucent resin will be described.

As a method for sealing the LED chip with a resin, a method for mounting an LED chip in each of a plurality of regions provided in a circuit substrate (referred to as the “substrate” occasionally hereinafter) and sealing the LED chips in a lump with a resin has been proposed (refer to Japanese Patent Laying-Open No. 2006-106479 (pp. 10 to 11, FIG. 4), for example). Then, a sealed body in which the plurality of LED chips are sealed with the resin all at once is cut and separated by the region, so that one LED package corresponding to one region is completed.

However, according to the above conventional technique, the problem is that heat radiation characteristics as the LED package is not sufficient. Especially, when a printed substrate formed of a glass epoxy substrate is used as the substrate, this problem is evident. In addition, this problem becomes more evident as an output of the LED package becomes high recently (increase in light flux per LED package).

### SUMMARY OF THE INVENTION

The present invention has been made to solve the above problems and it is an object of the present invention to provide a resin-sealed light emitting device having satisfactory heat radiation characteristics and its production method.

The following parenthetic reference numerals and symbols are shown to easily relate each word in the following description to a component shown in the drawings. In addition, the allocation of the reference numerals and symbols does not mean that significance of each word is limited to the component shown in the drawing in its interpretation.

In order to solve the above problems, a resin-sealed light emitting device (1A, 1B, 14, 19, 21, 23, 25) according to the present invention has a circuit substrate (15) having one or more regions (16), a recessed part (26) provided with respect to each of one or more regions (16), in one surface of circuit substrate (15), one or more LED chips (3) mounted on each recessed part (26), and a translucent sealing resin (4) provided so as to cover at least recessed part (26). Resin-sealed light emitting device (1A, 1B, 14, 19, 21, 23, 25) includes one setting pattern (5) provided on a bottom surface of recessed part (26) on which one or more LED chips (3) are set, or plurality of setting patterns (5) on which LED chips (3) are set, respectively; a slanted surface (9) provided on a side surface of recessed part (26); a light reflection part (10) provided on slanted surface (9); a wiring pad (8) provided on the bottom surface of recessed part (26) to give and receive an electric signal to and from one or more LED chips (3); a conductive material (13) to electrically connect an electrode provided in one or more LED (3) chips to wiring pad (8); an external terminal (12) provided on the other surface or the one surface of circuit substrate (15) to electrically connect resin-sealed light emitting device (1A, 1B, 14, 19, 21, 23, 25) to an external device; a wiring pattern (10) to electrically connect wiring pad (8) to external terminal (12); and one or more heat radiating patterns (7) provided to radiate a heat generated in one or more LED chips (3) outside resin-sealed light emitting device (1A, 1B, 14, 19, 21, 23, 25). One or more heat radiating patterns (7) are connected to one setting pattern (5) or plurality of setting patterns (5).

Resin-sealed light emitting device (1A, 1B, 14, 19, 21, 23, 25) as described above may be formed by separating a part formed of plurality of regions (16) into individual bodies, or may be formed by separating them into individual bodies by each region (16).

Moreover, according to resin-sealed light emitting device (1A, 1B, 14, 19, 21, 23, 25) as described above, circuit substrate (2, 15) may be formed of any one of a silicon substrate, a resin-based substrate, a metal-based substrate, and ceramic-based substrate.

Furthermore, according to resin-sealed light emitting device (1A, 1B, 14, 19, 21, 23, 25) as described above, light reflection part (10) may be formed of a metal layer.

In addition, according to resin-sealed light emitting device (1A, 1B, 14, 19, 21, 23, 25) as described above, a lens (20) formed of sealing resin (4) may be provided in region (16).

In addition, according to resin-sealed light emitting device (1B, 14) as described above, light emitted outside through sealing resin (4) may be white light substantially. For example, the white light is provided by mounting plurality of LED chips (3) emitting lights having different wavelengths on one or more setting patterns (5). Alternatively, the white light is provided also by mounting one or more LED chips (3) emitting lights having a predetermined wavelength on one or more setting patterns (5) and mixing a predetermined fluorescent body to sealing resin (4).

A manufacturing method of a resin-sealed light emitting device (1A, 1B, 14, 19, 21, 23, 25) according to the present invention is a production method of the following resin-sealed light emitting device. The resin-sealed light emitting device has a circuit substrate (15) having one or more regions (16), a recessed part (26) provided with respect to each of one or more regions (16), in one surface of circuit substrate (15), one or more setting patterns (5) provided on a bottom surface of recessed part (26), one or more LED chips (3) mounted on one setting pattern (5) or one LED chip (3) mounted on each of setting patterns (5), a wiring pad (8) provided on the bottom surface of recessed part (26), a conductive material (13) to electrically connect an electrode provided in one or more LED chips (3) to wiring pad (8), an external terminal (12) provided on the other surface or the one surface of circuit substrate (15) to give and receive an electric signal to and from an external device, a wiring pattern (10) to electrically connect-wiring pad (8) to external terminal (12) and serve also as a light reflection part, a heat radiating pattern connected to the setting pattern and provided to radiate a heat generated in the LED chip outside, and a translucent sealing resin (4) provided so as to cover at least recessed part (26). The above production method includes the steps of preparing a mold composed of an upper mold (28) and a lower mold (29); holding circuit substrate (15) as described above in the upper mode with recessed part (26) facing downward; filling a cavity (32) provided in lower mold (29) with a translucent fluid resin (34); arranging upper mold (28) and lower mold (29) so as to be opposed to each other; dipping plurality of LED chips (3) provided on the one surface of circuit substrate (15) into fluid resin (34) while upper mold (28) and lower mold (29) are clamped; forming a sealed body (14) by hardening fluid resin (34) and forming sealing resin (4) in a lump under the condition that upper mold (28) and lower mold (29) are clamped; separating upper mode (28) and lower mode (29); taking out sealed body (14); and separating sealed body (14) into individual bodies each containing at least one region in the plurality of regions.

According to the above production method, for example, a rotation blade, a band saw, a wire saw, a water jet or a laser beam can be used in the separating step.

Moreover, according to the above production method, circuit substrate (2, 15) may be formed of any one of a silicon substrate, a resin-based substrate, a metal-based substrate, and a ceramic-based substrate.

Furthermore, according to the above production method, a lens (20) is preferably formed of sealing resin (4) in each of plurality of regions (16), in the step for forming sealed body (14).

In addition, according to the above production method, plurality of LED chips (3) emitting lights having different wavelengths may be mounted on one or more setting patterns (5) so that light emitted outside through sealing resin (4) becomes white light substantially, Alternatively, one or more LED chips (3) emitting lights having a predetermined wavelength may be mounted on one or more setting patterns (5) and a predetermined fluorescent body may be mixed into sealing resin (4) so that the light emitted outside through sealing resin (4) becomes the white light substantially.

In addition, the above production method may have the step of providing a film (33) in a tensioned state along a mold surface of the lower mold defining a part of cavity (32) before the step of filling cavity (32) with fluid resin (34).

According to the present invention, setting pattern (5) on which LED chip (3) is set, and heat radiating pattern (7) to radiate the heat generated in LED chip (3) outside resin-sealed light emitting device (1A, 1B, 14, 19, 21, 23, 25) are provided, and setting pattern (5) and heat radiating pattern (7) are connected. Thus, the heat generated in LED chip (3) can be radiated effectively outside resin-sealed light emitting device (1A, 1B, 14, 19, 21, 23, 25) through setting pattern (5) and heat radiating pattern (7) sequentially. Thus, the heat radiation characteristics of resin-sealed light emitting device (1A, 1B, 14, 19, 21, 23, 25) is improved. Therefore, the high reliability and long life of resin-sealed light emitting device (1A, 1B, 14, 19, 21, 23, 25) can be implemented.

In addition, according to the present invention, recessed part (26) is provided in each of one or more regions (16) in the one surface of circuit substrate (15), and light reflection part (10) is provided on slanted surface (9) of recessed part (26). Thus, one part of the light emitted from LED chip (3) is efficiently reflected by light reflection part (10) and emitted upward, for example. Therefore, in addition to the above effect, the luminance efficiency of resin-sealed light emitting device (1A, 1B, 14, 19, 21, 23, 25) is improved.

Furthermore, according to one example of the present invention, recessed part (26) is provided in each of plurality of region (16) in the one surface of circuit substrate (15), and one or more LED chips (3) mounted on each recessed part (26) are sealed all at once in entire circuit substrate (15). Thus, resin-sealed light emitting device (1A, 1B, 14, 19, 21, 23, 25) is produced by separating the sealed body into individual bodies by one or more regions (16) as needed. Therefore, in addition to the above effect, resin-sealed light emitting device (1A, 1B, 14, 19, 21, 23, 25) can be efficiently produced.

Moreover, according to one example of the present invention, in addition to the above effect, resin-sealed light emitting device (1A, 1B, 14, 19, 21, 23, 25) can be produced by using any one of the silicon substrate, the resin-based substrate, the metal-based substrate and the ceramic-based substrate as circuit substrate (2, 15).

Furthermore, according to one example of the present invention, in addition to the above effect, resin-sealed light emitting device (1A, 1B, 14, 19, 21, 23, 25) having lens (20) can be provided.

In addition, according to one example of the present invention, in addition to the above effect, when plurality of LED chips (3) emitting lights having different wavelengths are mounted on one or more setting patterns (5), the lights becomes an additive color mixture. Therefore, when the lights having the different wavelengths are optionally selected, resin-sealed light emitting device (1B, 14) emitting substantial white light can be provided. Furthermore, when one or more LED chips (3) emitting the light having the predetermined wavelength are mounted on one or more setting patterns (5) and the predetermined fluorescent body is mixed in sealing resin (4), resin-sealed light emitting device (1A, 1B, 14, 19, 21, 23, 25) emitting the substantial white light can be provided also.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are front vertical sectional views showing a resin-sealed light emitting device according to a first embodiment and a sealed body as an intermediate body in a production process of the resin-sealed light emitting device shown in FIG. 1A, respectively.

FIGS. 2A and 2B are front vertical sectional views showing a resin-sealed light emitting device according to a second embodiment and a sealed body as an intermediate body in a production process of the resin-sealed light emitting device shown in FIG. 2A, respectively.

FIG. 3 is a front vertical sectional view showing a resin-sealed light emitting device according to a third embodiment.

FIGS. 4A and 4B are front vertical sectional views showing a resin-sealed light emitting device according to a fourth embodiment and a resin-sealed light emitting device according to a first variation of this embodiment, respectively.

FIG. 5A is a front vertical sectional view showing a second variation of the fourth embodiment, and FIG. 5B is a right vertical sectional view showing a resin-sealed light emitting device shown in FIG. 5A.

FIG. 6A is a front vertical sectional view showing a resin-sealed light emitting device according to a fifth embodiment, and FIG. 6B is a right vertical sectional view showing the resin-sealed light emitting device shown in FIG. 6A.

FIGS. 7A and 7B are vertical sectional views showing processes until a substrate on which a plurality of LED chips are mounted is arranged so as to be opposed to a lower mold in which a cavity is filled with a fluid resin, in a production method of a resin-sealed light emitting device according to a sixth embodiment.

FIGS. 8A and 8B are vertical sectional views showing processes until a sealed body is formed by hardening the fluid resin, in the production method of the resin-sealed light emitting device according to the sixth embodiment.

FIGS. 9A and 9B are vertical sectional views showing processes until an LED package is completed by cutting the sealed body, in the production method of the resin-sealed light emitting device according to the sixth embodiment.

### DESCRIPTION OF THE PREFERRED EMBODIMENTS

A sealed body (14) containing a substrate (15) having a plurality of regions (16) is separated into individual bodies to produce an LED package (1A). LED package (1A) includes an LED chip (3) mounted in a recessed part provided in one surface of a substrate (2), a sealing resin (4) provided on an entire surface of region (16), a setting pattern (5) provided on an inner bottom surface of the recessed part on which LED chip (3) is set, a wiring pattern (10) provided on a slanted surface (9) of the recessed part and serving as a light reflection part also, a wiring pad (8) provided on the inner bottom surface of the recessed part, a wire (13) to connect an electrode of LED chip (3) to wiring pad (8), an external terminal (12) provided on the other surface of substrate (2), a connection part (11) contained in wiring pattern (10) connected to wiring pad (8), to connect wiring pad (8) and external terminal (12), and a heat radiating pattern (7) provided on the other surface of substrate (2) to radiate a heat generated in LED chip (3) outside LED package (1A). Setting pattern (5) is connected to heat radiating pattern (7) by a connection part (6).

### First Embodiment

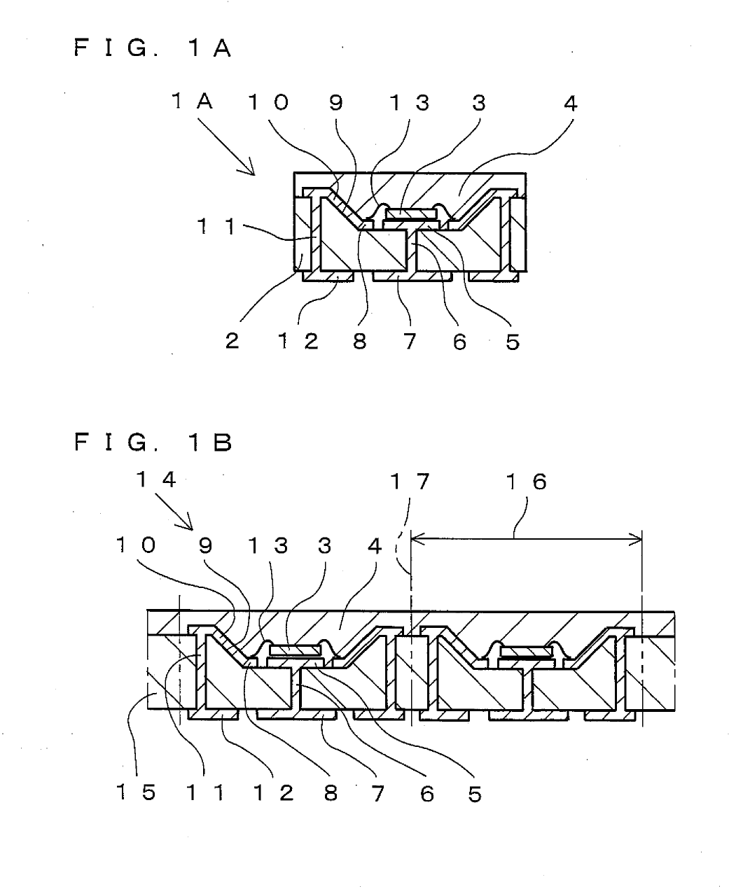

With reference to FIGS. 1A and 1B, a first embodiment regarding a resin-sealed light emitting device according to the present invention will be described. FIGS. 1A and 1B are front vertical sectional views showing a resin-sealed light emitting device according to this embodiment and a sealed body as an intermediate body in a production process of the resin-sealed light emitting device shown in FIG. 1A, respectively. Note that components are exaggerated or simplified in the drawings used in the following description so as to be easily understood. In addition, the same reference numeral is allotted to the same component in each drawing.

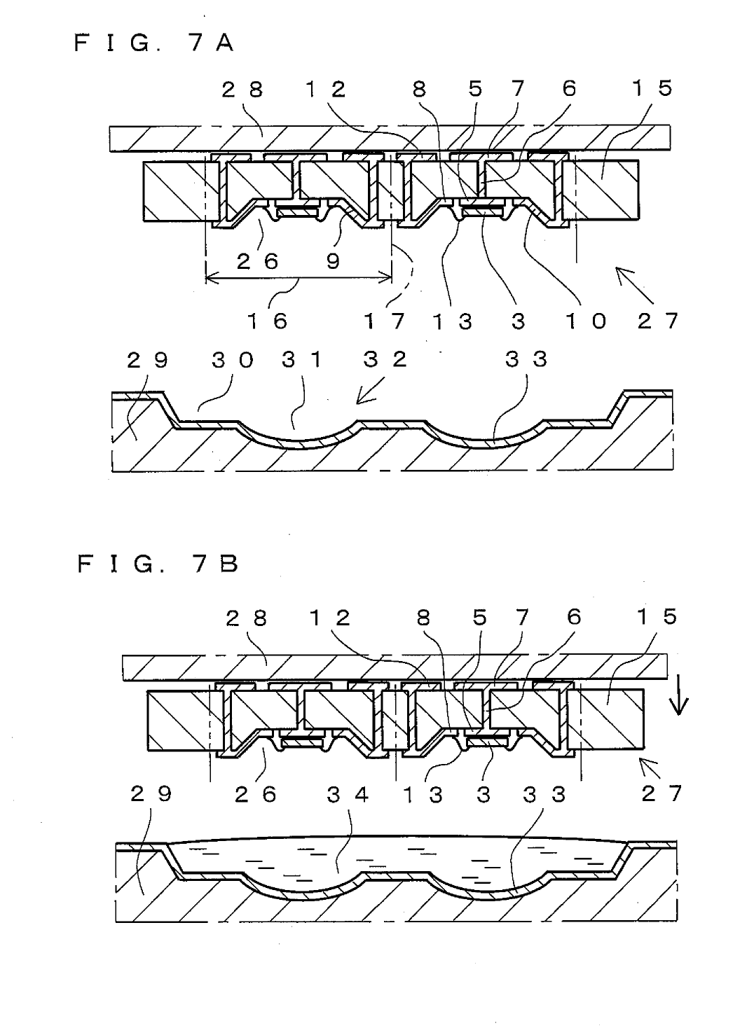

First, LED package 1A as the resin-sealed light emitting device shown in FIG. 1A will be described. The main components in LED package A are substrate 2, LED chip 3 mounted in the recessed part (see a recessed part 26 in FIG. 7A) provided in one surface (an upper surface in the drawing) of substrate 2, and a translucent sealing resin 4. Setting pattern 5 is formed on the bottom surface of the recessed part, and LED chip 3 is mounted on setting pattern 5 with a conductive paste (not shown) interposed therebetween. Setting pattern 5 is connected to heat radiating pattern 7 provided on the other surface (a lower surface in the drawing) of substrate 2 through a connection part (through hole) 6 penetrating substrate 2.

Wiring pad 8 is formed on the bottom surface of the recessed part, and slanted surface 9 is provided on a side surface of the recessed part. Wiring pattern 10 is connected to wiring pad 8, and wiring pattern 10 is formed so as to extend obliquely upward along slanted surface 9. A part of wiring pattern 10 formed on slanted surface 9 serves also as the light reflection part. Wiring pattern 10 is drawn out from the one surface of substrate 2 to the other surface thereof, through connection part 11 constituting one part of wiring pattern 10. Thus, wiring pattern 10 is connected to external terminal 12 provided on the other surface. External terminal 12 is used for electrically connecting LED package 1A to an external device composed of a printed substrate and the like on which LED package 1A is mounted. The electrode (not shown) of LED chip 3 and wiring pad 8 are connected by wire (metal thin wire) 13 formed by wire bonding. In addition, a light reflection part that is electrically irrelevant to wiring pattern 10 may be formed at a region on slanted surface 9 other than the region in which wiring pattern 10 is formed.

Next, sealed body 14 shown in FIG. 11 will be described. Sealed body 14 is the intermediate body in the production process of LED package 1A. Sealed body 14 has substrate 15, and substrate 15 has regions 16 sectioned in a reticular pattern. FIG. 1B shows an example in which four (=2×2) regions 16 are provided for descriptive purposes. Much more regions can be provided on substrate 15 in practice.

A cutting-plane line 17 is virtually illustrated at a boundary of regions 16 shown in FIG. 1B. The recessed part (having no reference numeral) is formed in each region 16, and setting pattern 5 is formed on the bottom surface of the recessed part. Here, sealed body 14 is cut along cutting-plane line 17 and separated into individual bodies, so that LED package 1A corresponding to each region 16 is completed. Therefore, sealed body 14 can be regarded as the intermediate body in the production process of LED package 1A. In addition, substrate 2 in FIG. 1A corresponds to the one provided when substrate 15 in FIG. 1B is cut by region 16.

A description will be given of a material used in some components of LED package 1A. First, substrate 2 is formed of any one of a silicon substrate (silicon wafer), a resin-based substrate, a metal-based substrate and a ceramic-based substrate. Here, when the silicon substrate is used, the recessed part is formed by etching and connection part 11 is formed by a well-known method (for example, Fujikura Technical Review, No 109, pp. 60-63, Fujikura Ltd., October 2005). Thus, when the recessed part is formed by etching, slanted surface 9 in the recessed part is a mirror surface. In addition, when the resin-based substrate, the metal-based substrate or the ceramic-based substrate is used, the recessed part can be formed by machining. In addition, as the resin-based substrate, a three-dimensionally molded circuit substrate (MID; Molded Interconnect Device) may be used.

In addition, setting pattern 5, connection part 6, heat radiating pattern 7, wiring pad 8, wiring pattern 10 serving also as the light reflection part, connector part 11, and external terminal 12 are formed of metal such as copper and aluminum. The patterns and external terminal 12 formed of copper are plated with gold. Wire 13 is formed of gold, aluminum and the like.

In addition, translucent sealing resin 4 is formed of a thermo-setting resin such as a silicon resin and an epoxy resin. Thus, a fluorescent body is optionally added to sealing resin 4 based on wavelengths of light from LED chip 3 and light to be emitted from LED package 1A. For example, when LED chip 3 emits blue light and light to be emitted from LED package 1A is white light, a yellow fluorescent body is added to sealing resin 4.

The resin-sealed light emitting device according to this embodiment, that is, LED package 1A has the following characteristics. First, a heat generated in LED chip 3 is radiated from heat radiating pattern 7 provided on the other surface of substrate 2 (lower surface in the drawing) through the conductive paste (not shown), setting pattern 5 and connection part 6 sequentially. Thus, when heat radiating pattern 7 is thermally connected to a heat radiating unit of the external device (for example, copper foil of the printed substrate and a heat sink provided in the external device), the heat generated in LED chip 3 is effectively radiated outside LED package 1A. Therefore, since heat radiation characteristics of LED package 1A is improved, high reliability and long life can be implemented in LED package 1A.

Secondly, light emitted from LED chip 3 is reflected upward by the light reflection part and emitted upward through sealing resin 4. Thus, luminance efficiency of LED package 1A is improved. Especially, when the silicon substrate is used, since slanted surface 9 serving as the light reflection part is the mirror surface, this effect can be increased. In addition, when the resin-based substrate, the metal-based substrate or the ceramic-based substrate is used, since wiring pattern 10 serving as the light reflection part also is plated with gold, this effect can be increased. Here, according to this embodiment, sealing resin 4 functions as a flat lens.

Thirdly, when sealed body 14 is separated into individual bodies by region 16, LED package 1A corresponding to each region 16 is completed. Thus, LED package 1A can be efficiently produced.

In addition, according to this embodiment, several variations can be employed. Such variations can be also applied to other embodiments that will be described below. The variations are as follows.

As a first variation, setting pattern 5 on which a back surface (surface where light is not emitted) of LED chip 3 is put can be set at a specific potential. For example, the back surface of LED chip 3 is set at a GND potential (a potential of a ground terminal) with the conductive paste (not shown) interposed therebetween. In this case, setting pattern 5 functions as a grounding pattern as well as contributes to heat radiation. In addition, the grounding pattern may serve as a light reflection part on slanted surface 9 also.

In addition, according to this embodiment, the electrode (not shown) of LED chip 3 and wiring pad 8 are electrically connected by wire 13 provided by the wire bonding. Instead of the above, as a second variation, the electrode of LED chip 3 and wiring pad 8 may be electrically connected by flip-chip bonding. A conductive material such as a gold or solder bump, a conductive adhesive and an anisotropic conductive film is used in the electric connection by the flip-chip bonding. Thus, in this case, it is preferable that a high thermally-conductive material is applied between LED chip 3 and substrate 2.

In addition, according to this embodiment, when sealed body 14 is cut and separated into individual bodies, LED package 1A corresponding to each region 16 is completed. Instead of this, as a third variation, entire sealed body 14 containing all regions 16 may be one LED package without being cut. In this case, sealed body 14 is an individual body and sealed body 14 serves as one LED package.

Furthermore, as a fourth variation, all regions 16 may serve as one LED package by cutting and removing an unnecessary part provided at an outer periphery of sealed body 14. In this case, sealed body 14 serves as one LED package composed of four (2×2=4) regions. According to the third and fourth variations, although the one LED package has four LED chips 3, the number of LED chip 3 contained in the one LED package can be increased. For example, when a large-sized substrate, silicon wafer having a diameter of 200 mm or 300 mm is used, a large resin-sealed light emitting device (surface luminous body) can be efficiently produced.

In addition, as a fifth variation, plural regions 16 composed of one part of four regions 16 may serve as one LED package by cutting sealed body 14. For example, two (1×2=2 or 2×1=2) regions 16 may constitute one LED package. Therefore, a square or elongated planar LED package containing plurality of LED chips 3 can be easily produced. In addition, the sealed body containing more regions, sixteen (4×4) regions 16, for example may be cut to produce two LED packages containing two (1×2) regions 16, one LED package containing four (2×2) regions 16, and one LED package containing eight (2×4) regions 16.

Furthermore, as a sixth variation, plurality of LED chips 3 contained in the one LED package in the fourth or fifth variation may be LED chips emitting red ( ), green (G), blue (B) lights, respectively. Thus, it is preferable that adjacent LED chips 3 are constituted so as to emit lights having different colors. Thus, the light emitted from the LED package becomes substantial white light as an additive color mixture of the three colors of R, G and B. Thus, the LED package (surface luminous body) emitting the substantial white light can be provided.

### Second Embodiment

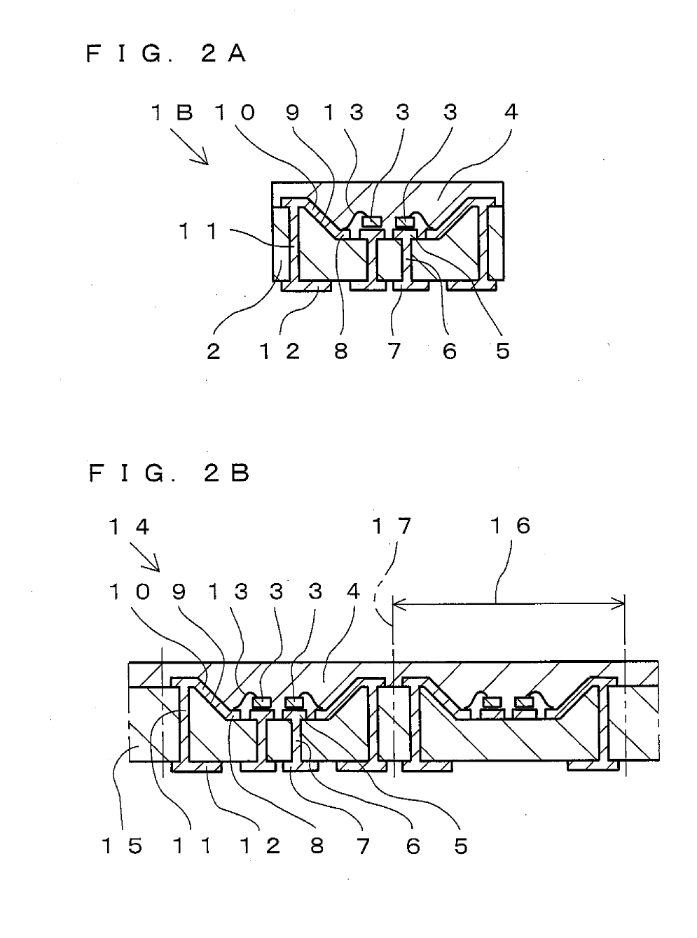

With reference to FIGS. 2A and 2B, a second embodiment regarding the resin-sealed light emitting device in the present invention will be described. FIGS. 2A and 2B are front vertical sectional views showing a resin-sealed light emitting device according to this embodiment and a sealed body as an intermediate body in a production process of the resin-sealed light emitting device shown in FIG. 2A, respectively.

According to this embodiment, as shown in FIG. 2A, plurality of LED chips 3 are mounted in a recessed part (having no reference numeral) provided in one surface (an upper surface in the drawing) of substrate 2. More specifically, one LED chip 3 is mounted on each of three setting patterns 5 provided in the recessed part. Therefore, three LED chips 3 are mounted on the recessed part (only two of them are shown in the drawing). Thus, three LED chips 3 emit R, G and B lights, respectively. Thus, the light emitted from an LED package 1B is substantially white light as an additive color mixture of the R, G and B colors. Therefore, according to this embodiment, in addition to the same characteristics as in the first embodiment, LED package 1B emits the substantial white light. Note that each of three setting patterns 5 is provided with connection part 6 and heat radiating pattern 7.

As a first variation of this embodiment, three LED chips 3 emitting the same color light may be mounted in the recessed part. In this case, LED package 1B has superior luminance efficiency. The number of LED chips 3 emitting the same color light is to be two or more.

In addition, according to the above example, three setting patterns 5 are provided in the recessed part and each of three LED chips 3 is mounted on each setting pattern 5, and setting pattern 5 is connected to heat radiating pattern 7 through connection part 6. Instead of the above, as a second variation, three LED chips 3 may be mounted on one common setting pattern 5. Thus, three or more connection parts 6 can be provided on one common setting pattern 5. Thus, since the heat can be more efficiently radiated from three LED chips 3, the heat radiation characteristics are improved in LED package 1B.

In addition, as a third variation, when three LED chips 3 have different heat generation characteristics, sizes of setting pattern 5, connection part 6 and heat radiating pattern 7 may be varied based on the heat generation characteristics of them. For example, in a case where LED chip 3 has a high heating value, the areas of setting pattern 5 and heat radiating pattern 7 are to be increased to increase a sectional area of connection part 6. Thus, even when the heat generation characteristics of three LED chips 3 are different, LED package 1B can have excellent heat radiation characteristics.

### Third Embodiment

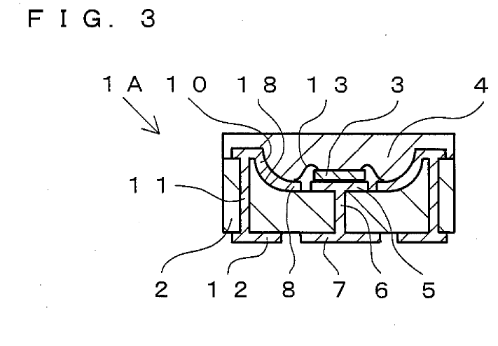

With reference to FIG. 3, a third embodiment regarding the resin-sealed light emitting device according to the present invention will be described. FIG. 3 is a front vertical sectional view showing a resin-sealed light emitting device according to this embodiment.

As shown in FIG. 3, according to this embodiment, a slanted surface provided on a side surface of a recessed part is a curved surface 18. Thus, wiring pattern 10 serving also as the light reflection part is formed on this curved surface. Thus, light emitted from LED chip 3 can be efficiently reflected upward by the light reflection part when a curvature of curved surface 18 is appropriately set. Therefore, according to this embodiment, in addition to the same characteristics in the first embodiment, LED package 1A has superior luminance efficiency.

Here, a method for forming curved surface 18 provided on the side surface of the recessed part will be described. When the silicon substrate is used, curved surface 18 can be provided by forming the recessed part by isotropic etching. Since curved surface 18 formed by the isotropic etching is a mirror surface, the light emitted from LED chip 3 can be efficiently reflected upward even at a part in which wiring pattern 10 is not formed. In addition, when the resin-based substrate, the metal-based substrate or the ceramic-based substrate is used, such a curved surface is provided by forming the recessed part by machining.

### Fourth Embodiment

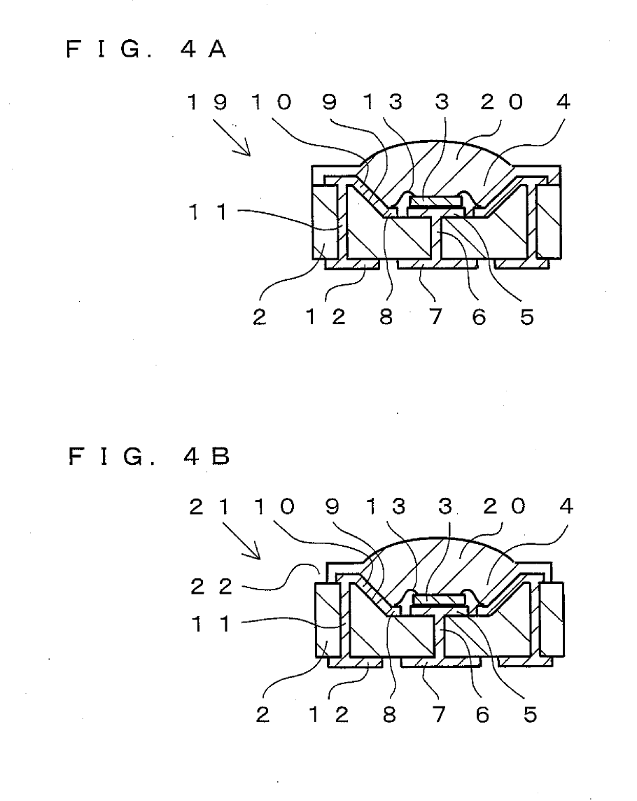

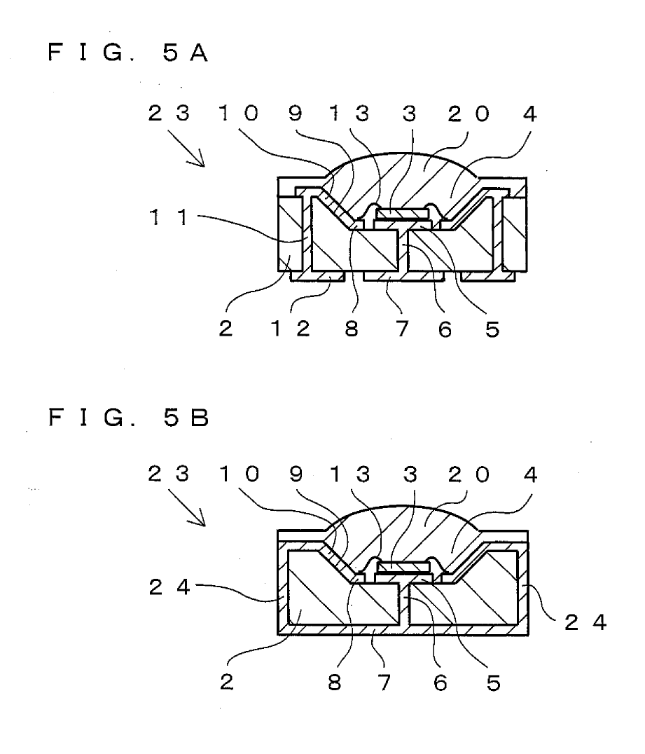

With reference to FIGS. 4A, 4B, 5 A and 5B, a fourth embodiment regarding the resin-sealed light emitting device according to the present invention and its variation will be described. FIGS. 4A and 413 are front vertical sectional views showing a resin-sealed light emitting device according to this embodiment and a first variation of this embodiment, respectively. FIG. 5A is a front vertical sectional view showing a second variation of this embodiment, and FIG. 5B is a right vertical sectional view showing a resin-sealed light emitting device shown in FIG. 5A.

As shown in FIG. 4A, a lens (convex lens) 20 formed of sealing resin 4 is provided in an LED package 19 according to this embodiment. Thus, light emitted from LED chip 3 is focused by lens 20 and emitted upward. In addition, according to this embodiment, an upper surface of LED package 19 is entirely covered with sealing resin 4. Therefore, according to this embodiment, in addition to the same characteristics as in the first embodiment, LED package 19 has lens 20 and its entire upper surface is covered with sealing resin 4.

In addition, an LED package 21 shown in FIG. 4B is the first variation of this embodiment. According to LED package 21, an exposed part 22 that is not covered with sealing resin 4 is formed at a peripheral part of an upper surface. According to this variation, LED package 21 has lens 20 and exposed part 22 at the peripheral part of the upper surface in addition to having the same characteristics in the first embodiment. Therefore, according to this variation, a consumed amount of sealing resin 4 is reduced in a production process of LED package 21. In addition, the light is prevented from being emitted in an unnecessary direction (direction close to a horizontal direction in the drawing) in LED package 21. To produce LED package 21 according to this variation, sealing resin 4 may be formed without providing a connection part to connect lenses 20 formed of sealing resin 4.

In addition, an LED package 23 shown in FIGS. 5A and 5B is the second variation of this embodiment. According to LED package 23, setting pattern 5 and heat radiating pattern 7 are connected by a connection part 24 provided on a side surface of LED package 23 as well as by connection part 6. Connection part 24 is formed as follows. First, a plurality of connection parts (through holes) are formed along a cutting-plane line (see cutting-plane line 17 in FIG. 1B) used when LED package 23 is produced. Then, they are cut along the cutting-plane line. Thus, since the plurality of connection parts (through holes) are cut almost in the center, connection parts 24 are formed so as to be exposed at the state of being vertically elongated on the side surface of LED package 23. According to the second variation, since connection part 24 is exposed, heat generated in LED chip 3 is more efficiently radiated from heat radiating pattern 7 and connection part 24 outside LED package 23. Therefore, according to this embodiment, LED package 23 has lens 20 and more improved heat radiating characteristics in addition to the same characteristics as in the first embodiment.

In addition, according to the second variation, an exposed part that is not covered with sealing resin 4 may be formed at a peripheral part of an upper surface of LED package 23 like exposed part 22 in the first variation (see FIG. 4B). Thus, since a part of wiring pattern 10 connected to connection part 24 is exposed, LED package 23 has more improved heat radiation characteristics.

### Fifth Embodiment

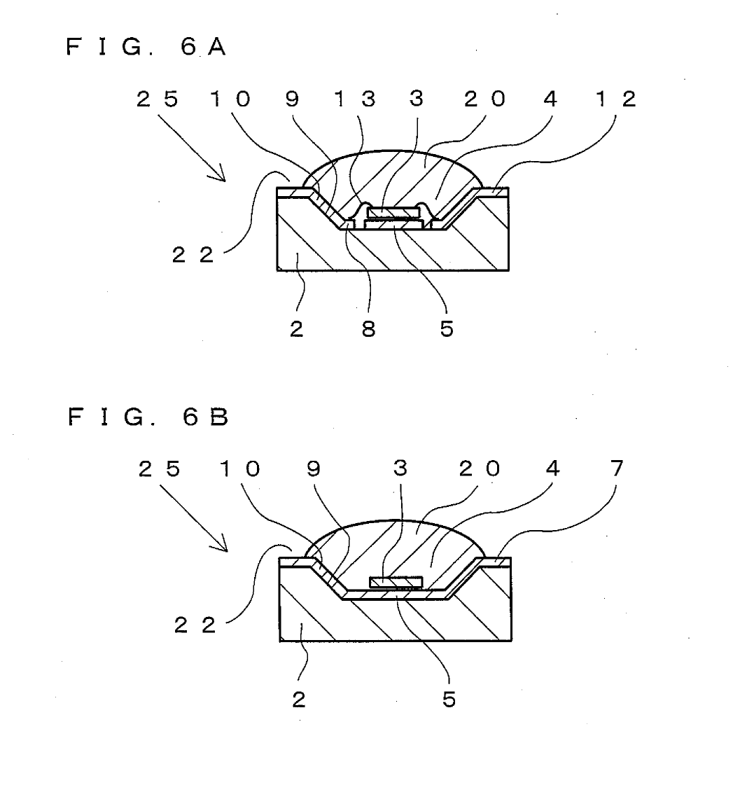

With reference to FIGS. 6A and 6B, a fifth embodiment regarding the resin-sealed light emitting device according to the present invention will be described. FIG. 6A is a front vertical sectional view showing a resin-sealed light emitting device according to this embodiment, and FIG. 6B is a right vertical sectional view showing the resin-sealed light emitting device shown in FIG. 6A.

As shown in FIGS. 6A and 6B, according to this embodiment, heat radiating pattern 7 and external terminal 12 are provided on a surface of substrate 2 on which LED chip 3 is mounted (an upper surface in the drawing) in an LED package 25. In addition, exposed part 22 that is not covered with sealing resin 4 is formed at a peripheral part of the upper surface. To produce LED package 25 according to this variation, lens 20 is formed of sealing resin 4 independently and sealing resin 4 is formed without providing a connection part for connecting lenses 20.

According to this embodiment, setting pattern 5, heat radiating pattern 7, wiring pad 8, wiring pattern 10 serving as the light reflection part also, and external terminal 12 are provided only on the upper surface of substrate 2. In addition, it is not necessary to provide the lower surface pattern and the connection part to connect the patterns on the upper and lower surfaces in substrate 2. Thus, since the constitution of substrate 2 can be simplified, substrate 2 can be produced at low cost. Therefore, a price of LED package 25 can be low. In addition, the same effect as in LED package 21 shown in FIG. 4B can be provided.

In addition, since heat radiating pattern 7 is not covered with sealing resin 4 partially, a heat generated in LED chip 3 is effectively radiated outside LED package 25. In addition, when setting pattern 5 is connected to the GND potential, heat radiating pattern 7 also functions as the external terminal to connect to the ground terminal of the external device (not shown). In addition, since external terminal 12 is not covered with sealing resin 4 partially, external terminal 12 can be used to electrically connect to the external device.

### Sixth Embodiment

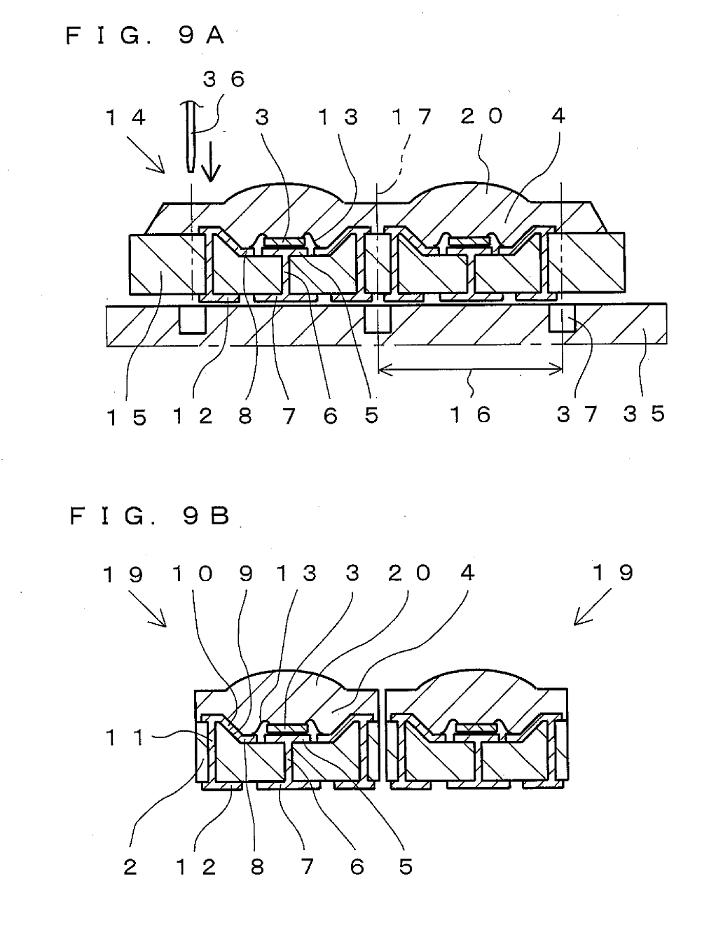

With reference to FIGS. 7A and 7B, to 9A and 9B, a sixth embodiment regarding a production method of the resin-sealed light emitting device according to the present invention will be described. FIGS. 7A and 7B are vertical sectional views showing processes until the substrate on which the plurality of LED chips are mounted is arranged so as to be opposed to a lower mold in which a cavity is filled with a fluid resin. FIGS. 5A and 5B are vertical sectional views showing processes until the fluid resin is hardened and the sealed body is formed. FIGS. 9A and 9B are vertical sectional views showing processes until the sealed body is cut and the LED package is completed.

First, as shown in FIG. 7A, a pre-seal substrate 27 having substrate 15 and LED chips 3 provided in recessed parts 26 provided in substrate 15 is prepared. In addition, an upper mold 28 and a lower mold 29 opposed to upper mold 28 are prepared. Here, a main cavity 30 is provided in lower mold 29, and sub cavities 31 serving as independent recessed parts at a position to be opposed to plurality of recessed parts 26 are provided in main cavity 30. An entire cavity 32 is constituted by main cavity 30 and sub cavities 31. Here, a planar configuration of recessed part 26 includes such as a polygonal configuration other than circular, ellipsoidal, oval, rectangular, and square.

Next, a release film 33 is provided along a mold surface of lower mold 29. When release film 33 is adsorbed, release film 33 is adhered to the mold surface of lower mold 29.

Then, pre-seal substrate 27 with recessed part 26 facing downward is held (fixed) on a mold surface of upper mold 28, by a well-known method such as adsorption and clamping. Here, when pre-seal substrate 27 is held on the mold surface of upper mold 28, centers of LED chip 3 and sub cavity 31 are aligned. Alternatively, after pre-seal substrate 27 is held on the mold surface of upper mold 28 at a position it is not opposed to lower mold 29, and then, the centers of LED chip 3 and sub cavity 31 may be aligned by moving upper mold 28.

Then, as shown in FIG. 7B, entire cavity 32 is filled with a fluid resin 34 such as thermo-setting resin. The resin that is liquid at room temperature (liquid resin) is dropped into entire cavity 32 by using a dispenser and the like to fill entire cavity 32 with fluid resin 34. Alternatively, after the liquid resin is dropped into entire cavity 32 at a position that is not opposed to upper mold 28, lower mold 29 may be moved to align the centers of LED chip 3 and sub cavity 31.

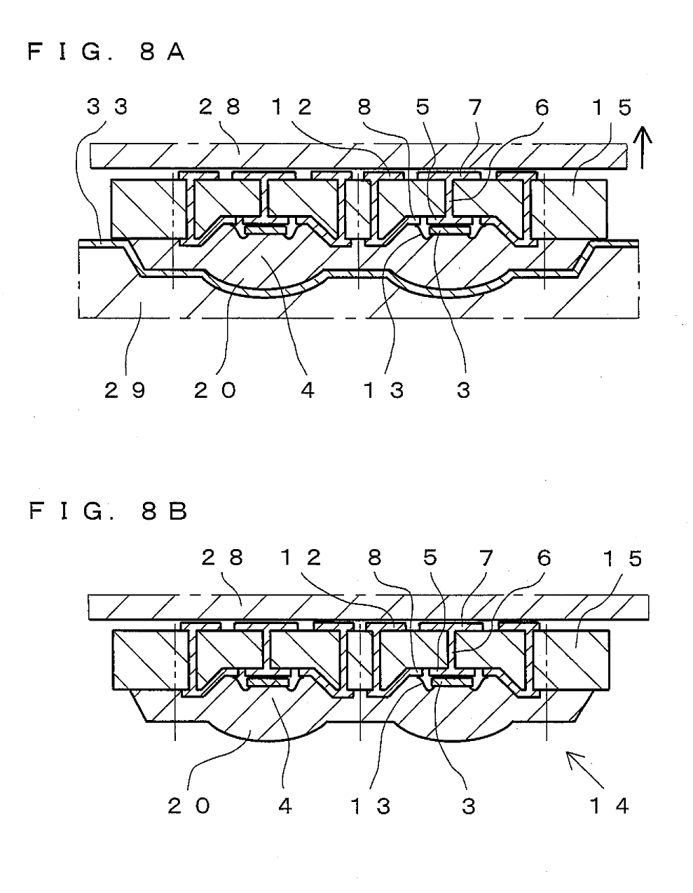

Then, as shown in FIG. 8A, upper mold 28 is lowered and upper mold 28 and lower mold 29 are clamped and closed. Then, in this clamped state, each LED chip 3 is dipped into fluid resin 34 and fluid resin 34 is hardened to form sealing resin 4. Here, sealing resin 4 hardened in sub cavity 31 (see FIG. 7A) constitutes lens 20. Then, upper mold 28 is raised and upper mode 28 and lower mold 29 are separated (see an arrow in FIG. 8A). Here, since release film 33 is used, sealing resin 14 (see FIG. 5B) can be easily separated from the mold surface of lower mold 29. In addition, when upper mold 28 and lower mold 29 are closed or opened, they are to be relatively moved in a perpendicular direction.

Thus, as shown in FIG. 5B, with the above processes, sealed body 14 having resin-sealed LED chip 3 and lens 20 whose center is aligned with the center of LED chip 3, in each of recessed parts 26 (see FIGS. 7A and 7B) is completed. Then, sealed body 14 is removed from upper mold 28 by the adsorption. Then, sealed body 14 is sent to the next process by an appropriate transporting unit.

Then, as shown in FIG. 9A, sealed body 14 is held (fixed) on a table 35 of a cutting device with sealing resin 4 facing upward, by a well-known method such as adsorbing, adhering and clamping. Then, sealing resin 4 and substrate 15 are sequentially cut along each cutting plane line 17 by a rotation blade 36 of the cutting device. Here, the cutting process is performed until an outer periphery of rotation blade 36 reaches a clearance groove provided at a position corresponding to each cutting plane line 17, in table 35. Thus, sealed body 14 is completely cut (fully cut) along each cutting plane line 17 to separate into individual LED packages 19.

Thus, as shown in FIG. 9B, with the above processes, when sealed body 14 is fully cut out by region 16, each LED package 19 is completed. Note that the LED packages described in the first to fifth embodiments can be produced by the production method of the resin-sealed light emitting device according to this embodiment.

According to this embodiment, recessed part 26 is provided in each of regions 16 in the one surface of substrate 15, and LED chips 3 provided in recessed parts 26 are collectively sealed with the resin in substrate 15 as a whole. Thus, when sealed body is separated into individual bodies by one or more regions 16 as needed, the LED package is produced. Therefore, the LED package having a desired dimension and configuration can be effectively produced.

In addition, since plurality of LED chips 3 mounted on substrate 15 are soaked in fluid resin 34, and fluid resin 34 is hardened while the molds are clamped, to form sealing resin 4, the flow of fluid resin 34 viewed from the side of LED chip 3 is limited to a minimum distance in a vertical direction in FIG. 7B. Thus, since external force applied to wire 13 can be reduced, a defective fraction can be reduced.

In addition, entire cavity 32 is also filled with fluid resin 34 according to this embodiment by the following method. For example, a resin material in the form of powder, granule, block, disk, cylinder or sheet is supplied in entire cavity 32 and the resin material is heated and melted. When the resin material in the form of disk, cylinder or sheet is used, the dimension, configuration and number of the resin material may be determined based on the dimension and configuration of entire cavity 32. In this case also, the resin material is supplied to entire cavity 32 at the position not opposed to upper mold 28, and then lower mold 29 may be moved to align the centers of LED chip 3 and sub cavity 31.

In addition, sealing resin 4 may be formed by forming a part of a flat lens first, and then forming a part of the convex lens in use of a different mold. In this case, the materials constituting the part of the flat lens and the part of the convex lens may be varied optionally.

In addition, only sub cavity 31 may be provided in lower mold 29 without providing main cavity 30. In this case, as shown in FIGS. 6A and 6B, the LED package having lens 20 having no connection part around itself and an exposed part 22 in the vicinity of outer periphery can be produced. In addition, since lens 20 is independently formed and the connection part for connecting lenses 20 is not provided, the consumed amount of the sealing resin can be cut back in the production process of the LED package. In addition, the light is prevented from emitting in the unnecessary direction (direction close to the horizontal direction in the drawing) in the LED package.

The example of the LED package having the convex lens as lens 20 is shown in the above description. However, the present invention is not limited to this, and an LED package having a Fresnel lens as lens 20 can be produced, for example, by performing an appropriate process on the mold surface in sub cavity 31. Furthermore, many microcompact Fresnel lenses can be formed on the surface of sealing resin 4 by forming many fine patterns corresponding to the Fresnel lenses on the entire mold surface in entire cavity 32 regardless of whether sub cavity 31 is provided or not. In addition, an LED package having a concave lens as lens 20 can be produced. Therefore, according to this embodiment, the different types of LED packages each having functions of collecting light, diffusing light and emitting parallel light can be produced.

In addition, as release film 33, a release film in which a fine pattern is formed on the surface to be in contact with fluid resin 34 (upper surface in the drawing) can be used. In this case, the fine pattern is transferred to the surface of sealing resin 4, so that the fine pattern can be formed on the surface of sealing resin 4. In this case, release film 33 functions as a transferring mold.

Furthermore, sealed body 14 can be completed without using release film 33, depending on the characteristics of the material constituting lower mold 29 and fluid resin 34. When a release mechanism in which external force applied to the LED package is small is employed, sealed body 14 can be also made without using release film 33.

In addition, sealed body 14 may be separated into individual LED packages 19 by forming a groove by cutting sealed body 14 in the middle of a thickness direction (half cut) and then applying external force to sealed body 14. Furthermore, any one of a rotation blade, a band saw, a wire saw, a water jet or a laser beam or combination of those may be used.

In addition, the electrode of LED chip 3 and wiring pad 8 may be electrically connected by a conductive material in use of the flip-chip bonding. In addition, a conductive material such as a gold or solder bump, a conductive adhesive and an anisotropic conductive film can be used in the electric connection by the flip-chip bonding.

The present invention is not limited to the above embodiments. The present invention can be employed by optionally and appropriately combining and changing or selecting the above configuration as needed without departing from the spirit and scope of the present invention.

Although the present invention has been described and illustrated in detail, it is clearly understood that the same is by way of illustration and example only and is not to be taken by way of limitation, the scope of the present invention being interpreted by the terms of the appended claims.

What is clawed is:

1. A resin-sealed light emitting device having a circuit substrate having at least one region, a recessed part provided with respect to each said region, in one surface of the circuit substrate, an LED chip mounted on each said recessed part, and a translucent sealing resin provided so as to cover at least said recessed part, comprising:
a setting pattern provided on a bottom surface of said recessed part to set said LED chip;
a slanted surface provided on a side surface of said recessed part;
a light reflection part provided on said slanted surface;
a wiring pad provided on the bottom surface of said recessed part to input and output an electric signal to and from said LED chip;
a conductive material to electrically connect an electrode provided in said LED chip to said wiring pad;
an external terminal provided on the other surface or said one surface of said circuit substrate to electrically connect said resin-sealed light emitting device to an external device;
a wiring pattern to electrically connect said wiring pad to said external terminal; and
a heat radiating pattern provided to radiate a heat generated in said LED chip outside said resin-sealed light emitting device, wherein
said heat radiating pattern is connected to said setting pattern.

2. The resin-sealed light emitting device according to claim 1, wherein
said resin-sealed light emitting device is produced by separating a sealed body containing said plurality of regions into individual bodies each containing at least one region in said plurality of regions.

3. The resin-sealed light emitting device according to claim 1, wherein
said circuit substrate includes any one of a silicon substrate, a resin-based substrate, a metal-based substrate, and a ceramic-based substrate.

4. The resin-sealed light emitting device according to claim 1, wherein
said light reflection part includes a metal layer.

5. The resin-sealed light emitting device according to claim 1, wherein
a lens formed of said sealing resin is provided in said region.

6. The resin-sealed light emitting device according to claim 1, wherein
light emitted outside through said sealing resin is substantially white light, and
said white light is provided by mounting said plurality of LED chips emitting lights having different wavelengths on said setting pattern, or by mounting said plurality of LED chips emitting lights having a predetermined wavelength on said setting pattern and mixing a predetermined fluorescent body to said sealing resin.

7. A manufacturing method of a resin-sealed light emitting device having a circuit substrate having at least one region, a recessed part provided with respect to each said region, in one surface of the circuit substrate, a setting pattern provided on a bottom surface of the recessed part, an LED chip mounted on said setting pattern, a wiring pad provided on the bottom surface of said recessed part, a conductive material to electrically connect an electrode provided in said LED chip to said wiring pad, an external terminal provided on the other surface or said one surface of said circuit substrate to input and output an electric signal to and from an external device, a wiring pattern to electrically connect said wiring pad to said external terminal and serve also as a light reflection part, a heat radiating pattern connected to said setting pattern and provided to radiate a heat generated in said LED chip outside, and a translucent sealing resin provided so as to cover at least said recessed part, comprising the steps of:
preparing a mold including an upper mold and a lower mold;
holding said circuit substrate having said plurality of regions, said plurality of setting patterns, said plurality of LED chips, said plurality of conductive material, said plurality of external terminals, said plurality of wiring patterns, and said plurality of heat radiating patterns, in said upper mold with said recessed part facing downward;
filling a cavity provided in said lower mold with a translucent fluid resin;
arranging said upper mold and said lower mold so as to be opposed to each other;
dipping said plurality of LED chips provided on said one surface of said circuit substrate into said fluid resin while said upper mold and said lower mold are clamped;
forming a sealed body having said plurality of regions by hardening said fluid resin and forming said sealing resin in a lump under the condition that said upper mold and said lower mold are clamped;
separating said upper mode and said lower mode;
taking out said sealed body; and
separating said sealed body into individual bodies each containing at least one region in said plurality of regions.

8. The manufacturing method of the resin-sealed light emitting device according to claim 7, wherein
a rotation blade, a band saw, a wire saw, a water jet or a laser beam is used in said separating step.

9. The manufacturing method of the resin-sealed light emitting device according to claim 7, wherein
said circuit substrate includes any one of a silicon substrate, a resin-based substrate, a metal-based substrate, and a ceramic-based substrate.

10. The manufacturing method of the resin-sealed light emitting device according to claim 7, wherein
a lens composed of said sealing resin is formed in each of said plurality of regions, in said step for forming the sealed body.

11. The manufacturing method of the resin-sealed light emitting device according to claim 7, further comprising the step of:
mounting said plurality of LED chips emitting lights having different wavelengths on said setting pattern; or
mounting said plurality of LED chips on said setting pattern and mixing a predetermined fluorescent body to said sealing resin, so that light emitted outside through said sealing resin is substantially white light.

12. The manufacturing method of the resin-sealed light emitting device according to claim 7, further comprising the step of:
providing a film in a tensioned state along a mold surface of said lower mold defining a part of said cavity before the step of filling said cavity with said fluid resin.
